(19) United States
(12) Patent Application Publication
(10) Pub. No.: US 2024/0213299 A1
(43) Pub. Date: Jun. 27, 2024

(54) MONOLITHIC INTEGRATION OF MULTICOLOR LIGHT EMITTING DIODES

(71) Applicant: The Regents of the University of Michigan, Ann Arbor, MI (US)

(72) Inventors: Zetian MI, Ann Arbor, MI (US); Xianhe LIU, Ann Arbor, MI (US); Yi SUN, Ann Arbor, MI (US); Yakshita MALHOTRA, Ann Arbor, MI (US); Yuanpeng WU, Ann Arbor, MI (US)

(21) Appl. No.: 18/573,969

(22) PCT Filed: Jun. 24, 2022
(86) PCT No.: PCT/US2022/034924

§ 371 Date: Dec. 22, 2023

Related U.S. Application Data
(60) Provisional application No. 63/215,130, filed on Jun. 25, 2021.

(51) Int. Cl. H01L 27/15

(52) U.S. Cl. CPC H01L 27/156

(57) ABSTRACT

Monolithic integration of multicolor light-emitting diodes with highly spatially uniform emission wavelength are realized in a single selective area epitaxy process. Pronounced emission peaks with very narrow spectral linewidths are also achieved. The indium contents and emission colors are tuned by precisely controlling the nanowire emitter diameter and lattice constant. The emission wavelengths exhibit small variations of only a few nanometers among individual nanowire emitters over an areal region.

### CROSS-REFERENCE TO RELATED APPLICATIONS

This is a conversion of PCT Patent Application No. PCT/US2022/034924 filed Jun. 24, 2022, which claims the priority to U.S. Provisional Patent Application 63/215,130 filed Jun. 25, 2021, both of which are incorporated herein in their entirety.

### BACKGROUND OF THE INVENTION

Displays based on mini-LEDs (light emitting diodes) and micro-LEDs are considered to be the next generation of display devices because such inorganic self-emissive LEDs hold the promise for enhanced brightness, extended lifetime, wide dynamic range, fast response, and high efficiency.

One crucial step is the integration of LEDs of different colors from blue to red. Although relatively large mini-LEDs of different colors made from different materials can be assembled to form large full color displays, the severe degradation of efficiency resulting from the inevitable top-down etching for processing micro-LEDs has prevented the realization of efficient micro-LEDs and hence micro-LED-based displays. The external quantum efficiency (EQE) of blue micro-LEDs by top-down etching is limited to around ten percent.

Furthermore, the yield of defect-free mass transfer and assembling of micro-LEDs is still low for practical production. Moreover, it has remained challenging to achieve high-efficiency LEDs operating in the deep-visible spectrum using conventional indium-gallium-nitride (InGaN) quantum wells. Efforts have been therefore devoted to developing dislocation-free InGaN nanowires by using bottom-up approaches to achieve high efficiency, multicolor emission from microscale devices.

### SUMMARY OF THE INVENTION

It has remained unknown if properties such as ultra-stable operation, ultra-narrow linewidth, and highly directional emission can be simultaneously achieved in multicolor LED arrays that are monolithically grown on a single chip, as any variations of the nanowire size may impact not only the photonic crystal bandgap but also the bandgap of the InGaN LED active region. In addition, given the dependence of In content on the geometry and spacing of nanowires, it is critically important to achieve highly uniform emission of nanowire LEDs for display applications, for example.

In embodiments according to the present disclosure, monolithic integration of multicolor LEDs with highly spatially uniform emission wavelengths are realized in a single selective area epitaxy process. Pronounced emission peaks with very narrow spectral linewidths are also achieved. The indium contents and emission colors are tuned by precisely controlling the nanowire emitter diameter and lattice constant. The emission wavelengths exhibit small variations of only a few nanometers among individual nanowire emitters over an areal region.

Devices in embodiments according to the present disclosure include a substrate and an array of photonic bandgap LEDs disposed on the substrate. The array includes photonic bandgap LEDs operable for emitting different colors of light. In an embodiment, the linewidth of at least one of the photonic bandgap LEDs is less than ten nanometers. In an embodiment, the linewidth of at least one of the photonic bandgap LEDs of the array is less than six nanometers. The different colors include red, green, blue, orange, and yellow. In embodiments, at least one of the photonic bandgap LEDs of the array has a current density that is greater than 1000 amperes per square centimeter at ten volts.

These and other objects and advantages of embodiments according to the present invention will be recognized by one skilled in the art after having read the following detailed description, which are illustrated in the various drawing figures.

### BRIEF DESCRIPTION OF THE DRAWINGS

The accompanying drawings, which are incorporated in and form a part of this specification and in which like numerals depict like elements, illustrate embodiments according to the present disclosure and, together with the detailed description, serve to explain the principles of the disclosure. The drawings are not necessarily drawn to scale, unless a scale is shown in the figure.

FIG. 1 is an example of a structure of a nanowire that can be used in micro-LEDs in embodiments according to the present disclosure.

FIG. 2 is an example of a method of fabricating nanowires for a micro-LED in embodiments according to the present disclosure.

FIG. 3 illustrates an array of nanowires in embodiments according to the present disclosure.

FIG. 4 is an example of monolithically integrated multicolor micro-LEDs in embodiments according to the present disclosure.

FIG. 5 illustrates wavelengths of the band edge mode at the gamma point of the fourth band in embodiments according to the present disclosure.

FIG. 6 illustrates current-voltage characteristics of micro-LEDs with emissions of different colors in embodiments according to the present disclosure.

FIG. 7A illustrates examples of the normalized electroluminescence (EL) spectra of monolithically integrated micro-LEDs with different colors in embodiments according to the present disclosure.

FIG. 7B illustrates a correlation between EL peak wavelength and the ratio of diameter to lattice constant in embodiments according to the present disclosure.

FIG. 8A illustrates an example of peak wavelength mapping of photoluminescence in embodiments according to the present disclosure.

FIG. 8B illustrates an example of peak wavelength mapping of EL in embodiments according to the present disclosure.

### DETAILED DESCRIPTION OF THE INVENTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The figures are not necessarily drawn to scale, and only portions of the devices and structures depicted, as well as the various layers that form those structures, are shown. For simplicity of discussion and illustration, only one or two devices or structures may be described, although in actuality more than one or two devices or structures may be present or formed. Also, while certain elements, components, and layers are discussed, embodiments according to the invention are not limited to those elements, components, and layers. For example, there may be other elements, components, layers, and the like in addition to those discussed.

In the design of next-generation nanowire photonic crystal micro-LEDs, both the electronic bandgap of individual nanowires and the optical resonance wavelength of the nanowire photonic crystal structure are dependent on the nanowire diameter and spacing. To simultaneously realize the integration of multicolor emission and pronounced photonic band edge mode from photonic crystals, the variation of the wavelength of the photonic band edge mode with nanowire diameter should match the variation of luminescence wavelength with nanowire diameter as much as possible. Furthermore, spacing among nanowires can neither be too large nor too small in order to maximize light-scattering among nanowires.

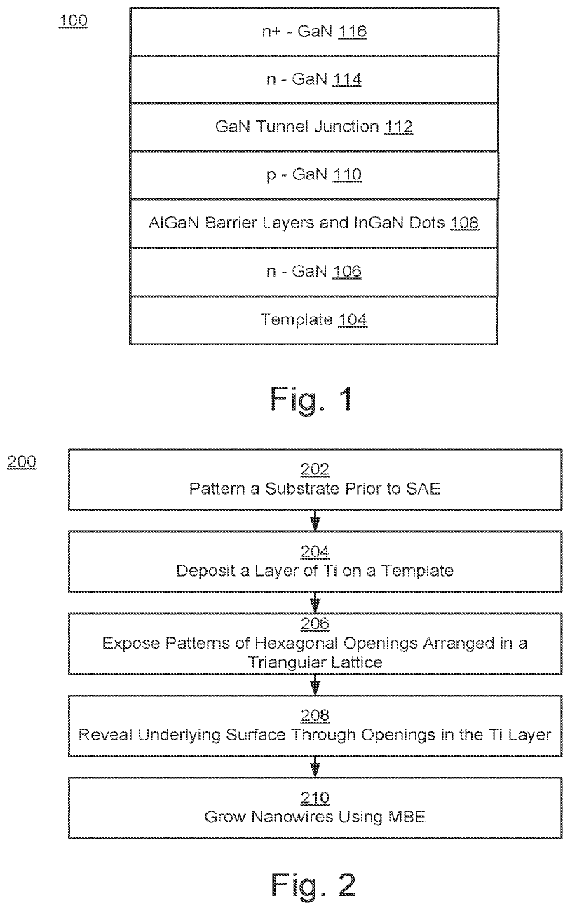

An example of a nanowire structure 100 of the disclosed micro-LEDs (which may also be referred to as nanowire LEDs or simply as LEDs) is shown in FIG. 1. In the embodiment of FIG. 1, the nanowire structure 100 of a micro-LED 100 can include a n-doped gallium nitride (n-GaN) layer 106, stacks 108 of InGaN quantum dots or disks and aluminum gallium nitride (AlGaN) barrier layers, a p-doped gallium nitride (p-GaN) layer 110, a GaN tunnel junction 112, an n-GaN layer 114, and a heavily doped n+-GaN contact layer 116. In an embodiment, the n-GaN layer 106 has a thickness of 450 nanometers (nm), there are six stacks of InGaN quantum dots and AlGaN barrier layers, the p-GaN layer 110 has a thickness of 120 nm, the n-GaN layer 114 has a thickness of 60 nm, and the n+-GaN contact layer 116 has a thickness of 12 nm. The stacks 108 of InGaN quantum dots and AlGaN barrier layers are disposed in alternating fashion: a layer of InGaN quantum dots may be between two AlGaN barrier layers, and an AlGaN barrier layer may be between two layers of InGaN quantum dots. The incorporation of Al in the GaN barrier layers promotes the formation of an AlGaN shell surrounding the active region, which can effectively confine charge carriers in the core region and minimize surface non-radiative recombination.

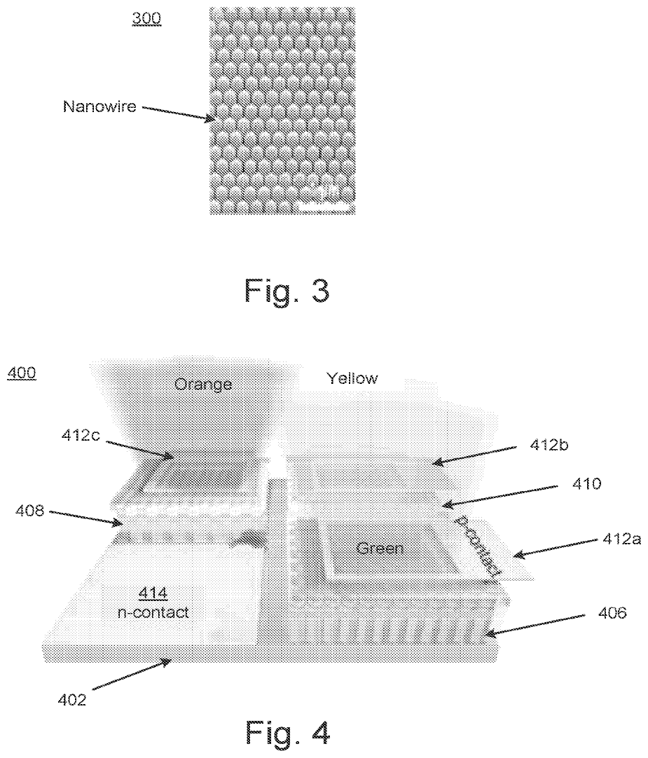

FIG. 2 is a flowchart 200 of an example of a method for fabricating a semiconductor device (e.g., a nanowire that can be used in the micro-LED 100 of FIG. 1) in an embodiment according to the present invention. An array of nanowires 300 formed by the disclosed selective area epitaxy (SAE) process is shown in FIG. 3. FIG. 3 is a top-down view of the array (that is, the tops of the nanowires are shown). With the assistance of a patterned mask as described below, highly uniform and regular nanowire arrays with well-defined diameters and spacing are achieved.

In block 202 of FIG. 2, a substrate is patterned prior to SAE. In block 204, a layer of Ti is deposited on an n-type GaN-on-sapphire template 104 (FIG. 1). In block 206, patterns of hexagonal openings arranged in a triangular lattice are exposed. In block 208, the surface of the underlying n-GaN is revealed through openings in the Ti layer. In block 210, the nanowires are grown using molecular beam epitaxy (MBE).

In one embodiment, in embodiments, prior to SAE, a substrate is first patterned using electron beam lithography. A ten nm thick layer of titanium (Ti) is deposited on n-type GaN-on-sapphire templates 104 (FIG. 1) with an electron beam evaporator. Then, polymethyl methacrylate (PMMA) is spin-coated and baked, and patterns consisting of hexagons arranged in a triangular lattice with a lattice constant a are exposed (where the lattice constant is a measure of the distance between adjacent nanowires). After developing the PMMA resist, the Ti is dry-etched using the PMMA as the mask, revealing the surface of underlying n-GaN in openings with a diameter d in the Ti layer (mask). PMMA is subsequently removed by soaking in AZ 400T photoresist stripper for two hours at 80 degrees Celsius (° C.). Then, the substrate is thoroughly cleaned before the MBE growth.

In embodiments, the array of nanowires 300 (FIG. 3) is grown in a Veeco GEN930 MBE system equipped with a radio frequency nitrogen plasma source and standard effusion and dopant cells. The growth of the n-type and p-type GaN layers is performed using a Ga beam equivalent pressure (BEP) of approximately 3.7×10⁻⁷ Torr under a high temperature that minimizes the growth on the Ti to achieve selectivity of growth. During the growth of the InGaN dots and an AlGaN barrier layers, the growth temperature is reduced and the nitrogen flow is boosted to allow for incorporation of In. In embodiments, the BEP is 3.5×10⁻⁸ Torr for Ga, 1.0×10⁻⁷ Torr for In, and 5.7×10⁻⁹ Torr for Al.

FIG. 4 illustrates an example of a device 400 that includes monolithically integrated multicolor micro-LEDs disposed on a single substrate 402 in embodiments according to the present disclosure. The term “monolithic” generally means that the micro-LEDs are integrated on a single chip. A micro-LED may also be referred to herein as photonic bandgap LED. A photonic bandgap LED has certain “disallowed” bands: there are certain wavelengths of light that are prevented from being propagated or emitted in a direction or directions, so that light is emitted only in an “allowed” band.

In the example of FIG. 4, an array of photonic bandgap LEDs includes a first set 406 of the photonic bandgap LEDs that emit light of a first color (e.g., green), a second set 408 of the photonic bandgap LEDs that emit light of a second, different color (e.g., orange), and a third set 410 of the photonic bandgap LEDs that emit light of a third, different color (e.g., yellow). Embodiments according to the present disclosure are not limited to three colors and are not limited to the colors just mentioned. For example, colors emitted by photonic bandgap LEDs can also include red and blue.

In embodiments, to fabricate the photonic bandgap LEDs with the array of nanowires 300 (FIG. 3), plasma-enhanced chemical vapor deposition of a 300 nm thick silicon dioxide (SiO₂) layer is performed for passivation and isolation. Standard photolithography is conducted to define the current injection window, and then SiO₂ in the current injection window is wet-etched to reveal the nanowires. Parylene is deposited and etched back to fill the gaps among the nanowires and reveal the tops of the nanowires. Metal contacts 412a, 412b, and 412c, consisting of, for example, five (5) nm of Ti and 5 nm of gold (Au) and a 180 nm thick indium tin oxide (ITO) layer, are subsequently deposited by electron beam evaporation and sputtering, respectively. An n-contact 414 is deposited on the n-GaN substrate using standard photolithography and metallization. Following the contact deposition is an annealing process at 350° C. under nitrogen ambient for one minute.

Finite-element method simulation was performed and the wavelength of the photonic band edge mode was calculated for an appropriate range of the ratio d a, where a is the lattice constant and d is the diameter of openings in the Ti mask. The selected mode is the gamma (Γ) point of the fourth band. Note that the value dis intentionally specified to be smaller than the final nanowire diameter due to lateral growth.

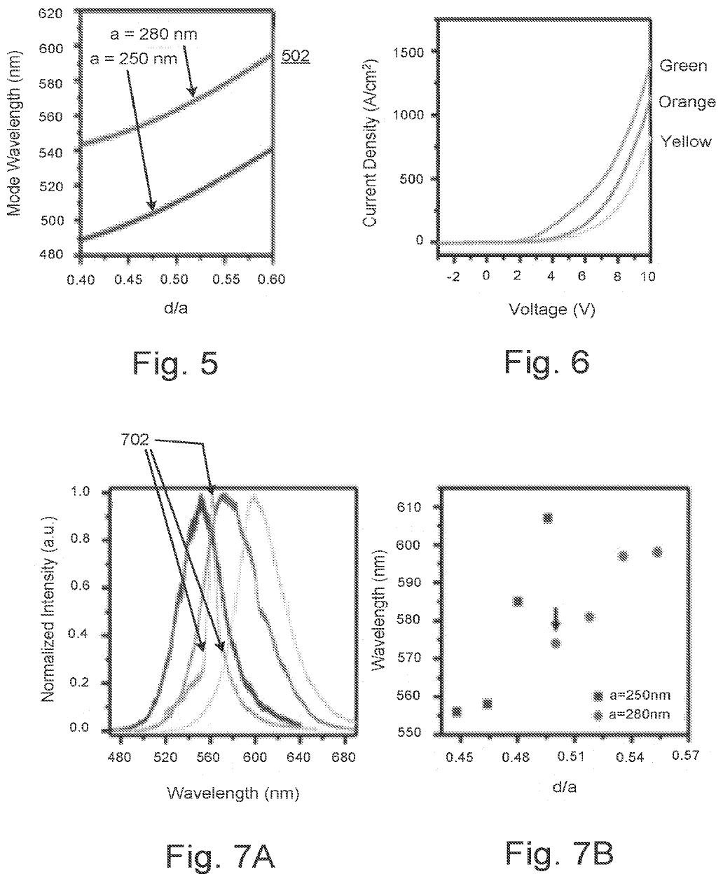

FIG. 5 illustrates wavelengths of the band edge mode at the Γ point of the fourth band in embodiments according to the present disclosure. As shown in FIG. 5, the mode wavelength exhibits a red shift as the ratio d a increases. If the emission wavelength of the actual active region exhibits a similar red shift (e.g., enhanced In incorporation) as the mode wavelength in FIG. 5, simultaneous realization of integration of multicolor emission and tailored emission properties due to the photonic band edge mode is expected. Therefore, two example lattice constants (a equal to 250 nm and 280 nm) are selected to provide a wide spectral range of approximately 500-600 nm.

Precise control over the nanowire geometry allows engineering of the geometry-dependent InGaN content and emission wavelength. FIG. 6 illustrates current-voltage characteristics of LEDs with emissions of different colors in embodiments according to the present disclosure. The current-voltage characteristics exhibit a small leakage under reverse bias. The current density can reach a few hundred or even above one thousand amperes per square centimeter (A/cm2) at ten volts (V), indicating the superior current conduction of nanowires. Doping levels and the growth of tunnel junction can be adjusted to reduce turn-on voltage, particularly for devices operating at longer wavelengths.

FIG. 7A illustrates examples of the normalized electroluminescence (EL) spectra of monolithically integrated micro-LEDs with different colors that indicate different In contents, in embodiments according to the present disclosure. The In content is a direct consequence of the geometry-dependent incorporation of In. When the lattice constant is fixed, a larger diameter reduces the spacing between adjacent nanowires, which in turn reduces the amount of Ga migrating from the lateral sidewall. The supply of In, however, is mostly dependent on direct impinging and less dependent on spacing and surface migration from a sidewall because of the high desorption rate of In at elevated growth temperatures. As a result, more Ga is present when the spacing is larger, leading to emission with shorter wavelengths.

FIG. 7B illustrates a correlation between EL peak wavelength and the ratio of diameter-to-lattice constant in embodiments according to the present disclosure. Examples of measured emission wavelengths and corresponding ratios of opening diameter-to-lattice constant are shown in FIG. 7B. It is observed that the emission wavelengths are heavily dependent on the diameter d of the openings and the lattice constant a. The lattice constants are 250 nm and 280 nm, respectively, for the two groups of micro-LEDs. As the ratio d a increases, the emission wavelengths exhibit a monotonic increase for both of those values of lattice constants. Taking advantage of this mechanism, different InGaN contents for green, yellow, and orange emissions are simultaneously achieved in just one step (in the same step) of the growth process.

Besides multicolor emission, narrow linewidth emission can be achieved from the disclosed micro-LEDs simultaneously. The curve 702 in FIG. 7A is measured from a three micrometer (μm)-by-three μm micro-LED fabricated from the nanowire array indicated by the arrow in FIG. 7B. It can be seen that this data point is the closest to the curve 502 in FIG. 5. Due to the precise periodic positioning of nanowires with precise diameters, the nanowire array functions as a photonic crystal structure where the band edge mode at the Γ point is supported. Light is coupled to the band edge mode at the Γ point of the photonic band structure, which emits light mostly in the “vertical” direction (in the direction of—parallel to—the longitudinal axis of a nanowire) due to the nearly negligible in-plane wavevector at the Γ point. The measured linewidth is therefore dominated by this mode and is as narrow as ten nm and less. Generally speaking, the term “linewidth” refers to the emission bandwidth; for example, linewidth may refer to the full-width at half-maximum (FWHM) of the emitted light.

Such narrow spectral linewidth and vertical emission directionality realized from the disclosed micro-LEDs are intriguing for greatly simplified optical systems and applications including ultrahigh resolution displays and near-eye display devices. The rest of the data points in FIG. 7B are not exhibiting pronounced narrow emission peak from the mode at the Γ point of the fourth band of the photonic band structure. To achieve monolithically integrated multicolor emission dominantly from the mode at the Γ point of the fourth band, a wider selection of the lattice constant a and of the ratio d a can be used. For example, a smaller value of the lattice constant a will blue-shift the entire curve as shown in FIG. 5, and a smaller ratio d a will accordingly blue-shift the luminescence wavelength to match the mode wavelength. Conversely, larger values of the lattice constant a and the ratio d a achieve the red emission. These can all be achieved simultaneously in a single epitaxy process by using the appropriate values of a and d a for different colors.

The uniformity of In content can be examined using a micro-photoluminescence (PL)/EL setup equipped with a 100× microscope objective lens and a spectrometer with a spectral resolution of 0.025 nm. The PL spectra are measured at various positions over a 200 μm square region with green emission, and the peak wavelength is estimated by fitting using a Gaussian function.

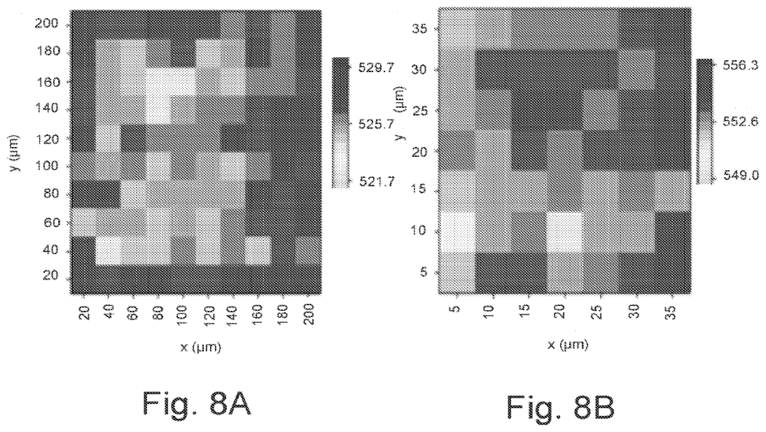

FIG. 8A illustrates an example of peak wavelength mapping of PL in embodiments according to the present disclosure. Despite each nanowire being an individual emitter, the peak wavelength is distributed in a relatively narrow range of 523.7 nm to 529.7 nm as shown in FIG. 8A. Such high spatial consistency of emission wavelength is attributed to the precise control over diameter and spacing of nanowires formed by the disclosed SAE technique. Similar measurements of EL spectra are performed over a 35 μm square region for a green nanowire LED.

FIG. 8B illustrates an example of peak wavelength mapping of EL in embodiments according to the present disclosure. The wavelengths are also distributed in a narrow spectral window from 550.7 nm to 554.9 nm as shown in FIG. 8B. Such high consistency of EL wavelength is also observed for orange nanowire LEDs.

Using the disclosed SAE technique, which allows for a precise control over nanowire diameter and spacing, monolithic integration of multicolor InGaN microLEDs is achieved together with a photonic crystal effect in a single growth (e.g., SAE) process. Due to the heavy dependence of InGaN content on the geometry of the nanowire array and the fine control over the growth process, multicolor nanowire microLEDs and highly uniform luminescence wavelength are achieved. Moreover, narrow emission spectral linewidths from micro-LEDs are achieved simultaneously. Multicolor light emitters with demanding light emission properties including wide color tunability, high color purity, and emission directionality are achievable. These features are particularly intriguing for next-generation ultrahigh resolution mobile displays and emerging near-eye virtual/mixed/augmented reality devices and systems.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A device, comprising:
a substrate; and
an array of photonic bandgap light-emitting diodes (LEDs) disposed on the substrate, wherein the array of photonic bandgap LEDs comprises:
a first plurality of the photonic bandgap LEDs operable for emitting light of a first color; and
a second plurality of the photonic bandgap LEDs operable for emitting light of a second color that is different from the first color;
wherein a linewidth of at least one of the photonic bandgap LEDs is less than ten nanometers.

2. The device of claim 1, wherein the first color and the second color are different colors selected from the group consisting of: red, green, blue, orange, and yellow.

3. The device of claim 1, wherein a linewidth of at least one of the photonic bandgap LEDs of the array is less than six nanometers.

4. The device of claim 1, wherein at least one of the photonic bandgap LEDs of the array has a current density that is greater than one thousand amperes per square centimeter at ten volts.

5. The device of claim 1, wherein the array of photonic bandgap LEDs comprises a photonic bandgap LED comprising a nanowire comprising:
a first n-doped gallium nitride (GaN) layer;
multiple stacks of indium gallium nitride (InGaN) quantum dots and aluminum gallium nitride (AlGaN) barrier layers;
a p-doped GaN layer;
a tunnel junction;
a second n-doped GaN layer; and
an n+-GaN contact layer.

6. The device of claim 1, wherein the first plurality of the photonic bandgap LEDs comprises nanowires having a first lattice constant and a first ratio of nanowire diameter-to-lattice constant, and wherein the second plurality of the photonic bandgap LEDs comprises nanowires having a second lattice constant different from the first lattice constant and a second ratio of nanowire diameter-to-lattice constant different from the first ratio.

7. The device of claim 1, wherein the first plurality of the photonic bandgap LEDs comprises nanowires having a first indium content, and wherein the second plurality of the photonic bandgap LEDs comprises nanowires having a second indium content different from the first indium content.

8. The device of claim 1, wherein the array of photonic bandgap LEDs comprises a plurality of nanowires, and wherein most of the light emitted by the array of photonic bandgap LEDs is in a direction parallel to the longitudinal axes of the nanowires.

9. A device, comprising:
a substrate; and
an array of photonic bandgap light-emitting diodes (LEDs) disposed on the substrate, wherein the array comprises:
a first plurality of the photonic band LEDs disposed on a first areal region of the substrate and comprising a plurality of first nanowires, wherein the plurality of first nanowires has a first lattice constant and a first ratio of nanowire diameter-to-lattice constant; and
a second plurality of the photonic band LEDs disposed on a second areal region of the substrate and comprising a plurality of second nanowires, wherein the plurality of second nanowires has a second lattice constant different from the first lattice constant and a second ratio of nanowire diameter-to-lattice constant different from the first ratio;
wherein a linewidth of at least one of the photonic bandgap LEDs of the array is less than ten nanometers.

10. The device of claim 9, wherein the first plurality of the photonic band LEDs are operable for emitting light of a first color, wherein the second plurality of the photonic band LEDs are operable for emitting light of a second color, and wherein the first color and the second color are different colors selected from the group consisting of: red, green, blue, orange, and yellow.

11. The device of claim 9, wherein a linewidth of at least one of the photonic bandgap LEDs of the array is less than six nanometers.

12. The device of claim 9, wherein a linewidth of at least one of the photonic bandgap LEDs of the array has a current density that is greater than one thousand amperes per square centimeter at ten volts.

13. The device of claim 9, wherein the array of photonic bandgap LEDs comprises a photonic bandgap LED comprising a nanowire comprising:
a first n-doped gallium nitride (GaN) layer;
multiple stacks of indium gallium nitride (InGaN) quantum dots and aluminum gallium nitride (AlGaN) barrier layers;
a p-doped GaN layer;
a tunnel junction;
a second n-doped GaN layer; and
an n+-GaN contact layer.

14. The device of claim 9, wherein most of the light emitted by the array of photonic bandgap LEDs is in a direction parallel to the longitudinal axes of the first nanowires and the longitudinal axes of the second nanowires.

15. A device, comprising:
a substrate; and
an array of photonic bandgap light-emitting diodes (LEDs) disposed on the substrate, wherein the array comprises:
a first plurality of the photonic band LEDs disposed on a first areal region of the substrate and comprising a plurality of first nanowires, wherein the first plurality of the photonic bandgap LEDs comprises nanowires having a first indium content; and
a second plurality of the photonic band LEDs disposed on a second areal region of the substrate and comprising a plurality of second nanowires, wherein the second plurality of the photonic bandgap LEDs comprises nanowires having a second indium content different from the first indium content;
wherein a linewidth of at least one of the photonic bandgap LEDs of the array is less than ten nanometers.

16. The device of claim 15, wherein the first plurality of the photonic band LEDs are operable for emitting light of a first color, wherein the second plurality of the photonic band LEDs are operable for emitting light of a second color, and wherein the first color and the second color are different colors selected from the group consisting of: red, green, blue, orange, and yellow.

17. The device of claim 15, wherein a linewidth of at least one of the photonic bandgap LEDs of the array is less than six nanometers.

18. The device of claim 15, wherein a linewidth of at least one of the photonic bandgap LEDs of the array has a current density that is greater than one thousand amperes per square centimeter at ten volts.

19. The device of claim 15, wherein the array of photonic bandgap LEDs comprises an LED comprising a nanowire comprising:
a first n-doped gallium nitride (GaN) layer;
multiple stacks of indium gallium nitride (InGaN) quantum dots and aluminum gallium nitride (AlGaN) barrier layers;
a p-doped GaN layer;
a tunnel junction;
a second n-doped GaN layer; and
an n+-GaN contact layer.

20. The device of claim 15, wherein most of the light emitted by the array of photonic bandgap LEDs is in a direction parallel to the longitudinal axes of the first nanowires and the longitudinal axes of the second nanowires.
